(19) United States
(12) Patent Application Publication
(10) Pub. No.: US 2026/0081548 A1
(43) Pub. Date: Mar. 19, 2026

(54) SYSTEM FOR PROCESSING A PRODUCT DURING ROTATION

(71) Applicant: SKF CANADA LIMITED, Scarborough (CA)

(72) Inventors: Timothy Andrew HARRIS, Calgary (CA); Gregory W. SMITH, Calgary (CA)

(21) Appl. No.: 18/887,150

(22) Filed: Sep. 17, 2024

(51) Int. Cl. H02P 23/14; B23Q 1/44; H01L 21/67; H02K 11/21; H02P 23/16

(52) U.S. Cl. CPC H02P 23/14; B23Q 1/44; H02K 11/21; H02P 23/16; H10P 72/0436

(57) ABSTRACT

A system for processing a product includes a tool that processes the product and a rotor assembly including a rotor supporting the product and a stator with actuator(s) exerting torque on the rotor. A tool controller operates the tool and transmits speed request signals including a desired speed of the rotor and a control pulse having a threshold value repeating at the expiration of a period proportional to a desired rotation period of the rotor at the desired speed. A rotor controller receives both the speed request signal and the control pulse, controls the stator actuator(s) such that the rotor rotates at the desired speed and phase, and transmits a rotor position pulse and/or phase information to the tool controller once every predetermined angular displacement of the rotor. The tool controller operates the tool based on the angular position of the rotor as calculated using information from the rotor controller.

### BACKGROUND OF THE INVENTION

The present invention relates to processing systems, and more particularly to control systems for coordinating tool operation with rotor operation.

Systems for processing products such as semiconductor wafers are known and typically include a tool, e.g., a heat lamp, a gas injector, etc., that performs a process on the product while the product is rotated about a central axis. In such systems, the product may be supported on a rotor that is angularly displaced by torque applied to the rotor from a stator. Typically, the tool must perform processing on specific portions of the product, such that a controller which operates the tool must be provided with information on the exact angular position of the product at any particular moment in time. Such information is normally provided to the tool controller from a controller which operates the rotor.

More specifically, the rotor is part of an assembly including at least one and generally a plurality of rotation sensors which each detect features on the rotor and sends this information to the rotor controller. The rotor controller determines the exact rotor position from information provided by the sensors and sends the rotor angular position information to the tool controller as a signal with a time stamp. As such, the tool controller is continuously informed of the angular position of the rotor at any point in time and is able to operate the tool(s) in accordance with this position information. Although a system for coordinating rotor angular position with tool processing of a product has been generally effective, the amount of information sent to the tool controller requires a continuous “polling” process, i.e., a process in which the tool controller requests and receives rotor position data, to determine the rotor angular position as such a process limits the accuracy of tool operation especially at higher rotor speeds.

### SUMMARY OF THE INVENTION

In one aspect, the present invention is a system for processing a product during rotation, the system comprising a tool configured to perform a process on the product and a rotor assembly including a rotor, the rotor being configured to support the product, and a stator including at least one actuator configured to exert magnetic torque on the rotor so as to angularly displace the rotor about a central axis. A tool controller is configured to operate the tool, to transmit a speed request signal including a desired rotation speed of the rotor and to transmit a control pulse having a threshold value repeating at the expiration of a pulse period, the pulse period being proportional to a desired period of rotation of the rotor at the desired rotation speed of the speed request signal. A rotor controller is configured to receive the speed request signal and the control pulse, to control the at least one actuator of the stator such that the rotor angularly displaces at the desired rotation speed and to transmit a rotor angular position pulse to the tool controller once every predetermined angular displacement of the rotor. The rotor controller is further configured to compare a time when the threshold value of the control pulse is received with a time that the rotor angular position pulse is transmitted and to adjust rotation speed of the rotor when there is a difference between the time the control pulse threshold value is received and the time the rotor angular position pulse is transmitted so as to at least minimize the time difference.

In another aspect, the present invention is again a system for processing a product during rotation comprising a tool configured to perform a process on the product and a rotor assembly including a rotor, the rotor being configured to support the product, and a stator including at least one actuator configured to exert magnetic torque on the rotor so as to angularly displace the rotor about a central axis. A tool controller is configured to operate the tool, to transmit a speed request signal including a desired rotation speed of the rotor, and to transmit a control pulse having a threshold value repeating at the expiration of a pulse period, the pulse period being proportional to a desired period of rotation of the rotor at the desired rotation speed of the speed request signal. A rotor controller is configured to receive the speed request signal, to control the at least one actuator of the stator such that the rotor angularly displaces at the desired rotation speed and to transmit a rotor position pulse and/or rotor phase information to the tool controller once every predetermined angular displacement of the rotor. The rotor controller is further configured to calculate an expected time of position pulse transmission based on the desired speed from the speed request signal, to compare the time the rotor angular position pulse and/or rotor phase information is transmitted to the expected time of position pulse transmission once every predetermined angular displacement of the rotor and to adjust the rotation speed of the rotor when there is a difference between the time the rotor angular position pulse and/or rotor phase information is transmitted and the expected time of position pulse transmission.

### BRIEF DESCRIPTION OF THE SEVERAL VIEWS OF THE DRAWINGS

The foregoing summary, as well as the detailed description of the preferred embodiments of the present invention, will be better understood when read in conjunction with the appended drawings. For the purpose of illustrating the invention, there is shown in the drawings, which are diagrammatic, embodiments that are presently preferred. It should be understood, however, that the present invention is not limited to the precise arrangements and instrumentalities shown. In the drawings:

FIG. 1 is more diagrammatic view of the basic components of the system of the present invention, indicating the transmission of signals and pulses and showing a rotor assembly in axial cross-section;

FIG. 2 is a top plan view of the rotor assembly, shown with certain components only;

FIG. 3 is a signal diagram showing a control pulse, a position pulse and a comparison of an expected time of position pulse transmission with the time of position pulse transmission when the control pulse period is multiple revolutions of a rotor; and

FIG. 4 is another signal diagram showing a control pulse, a position pulse and a comparison of an expected time of position pulse transmission with the time of position pulse transmission when the control pulse period is a fraction of a revolution of the rotor.

### DETAILED DESCRIPTION OF THE INVENTION

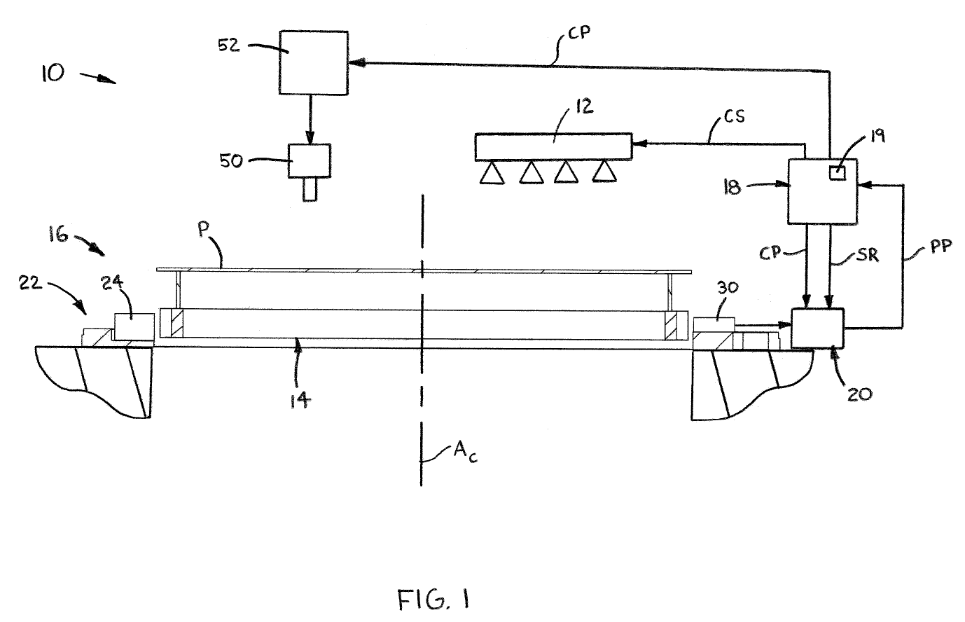

Referring to the drawings in detail, wherein like numbers are used to indicate like elements throughout, there is shown in FIGS. 1-4 a system 10 for processing a product P during rotation. The product P is preferably a semiconductor wafer, but may be another product or component on which processing is conducted during rotation of the product, such as for example, certain food products, etc. The processing system 10 basically comprises at least one tool 12, a rotor 14 provided by a rotor assembly 16, a tool controller 18 and a rotor controller 20. The tool 12 is configured to perform a process on the product P; with the preferred product P being a semiconductor wafer, the tool 12 may be a rapid thermal processing device such as a heat lamp for annealing sections of the wafer, an injector for injecting process gas that embeds within the wafer, etc. However, when the product P is an item other than a semiconductor wafer, the tool 12 is configured to perform any other process appropriate for the particular type of product P.

The rotor assembly 16 includes the rotor 14, which is configured to support the product P, and a stator 22 that includes at least one actuator 24 configured to exert magnetic torque on the rotor 14 so as to angularly displace the rotor 14 about a central axis A_{C}. Preferably, the stator 22 includes a plurality of the actuators 24 spaced circumferentially about the outer perimeter of the rotor 14, as described in further detail below. The tool controller 18 is configured to operate the tool 12, specifically by control signals CS, and to transmit a speed request signal SR to the rotor controller 20 that includes a desired rotation speed of the rotor 14. A new speed request signal SR is sent to the rotor controller 20 each time the tool controller 18 requires a change in rotation speed of the rotor 14 during tool operation, which typically occurs multiple times during the processing of each product P.

The rotor controller 20 is configured to receive the speed request signal SR and to control the at least one actuator 24 of the stator 22 such that the rotor 14 angularly displaces at the desired rotation speed. The rotor controller 20 is also configured to transmit a rotor angular position pulse PP to the tool controller 18 once every predetermined angular displacement of the of the rotor 14, preferably once a revolution so as to be referred to as a top dead center or “TDC” pulse, indicating that a reference point on the rotor 14 has returned to a starting angular position at the completion of each rotor revolution. However, the angular position pulse PP may be transmitted at any other desired angular displacement of the rotor 14, such as for example, every one hundred eighty degrees (180°), every one hundred twenty degrees (120°), etc. Further, in addition or as an alternative to the rotor angular position information, the rotor controller 20 may send a separate digital communication to the tool controller 18, such as the amount by which the rotor 14 leads or lags a desired angular phase of the rotor 14, indicating phase accuracy or phase offset of the rotor 14, so that the tool controller 18 adjusts tool operation based on this phase information.

The tool controller 18 operates the tool 12 based on the angular position of the rotor 14 as calculated by the tool controller 18 using the rotor angular position pulse PP and/or other rotor phase information from the rotor controller 20, e.g., the amount of phase lagging or leading from the desired angular position of the rotor 14. Specifically, the tool controller 18 includes a counter 19 having a clock, typically provided by a crystal oscillator, that tracks the time between receipt of each angular position pulse PP and/or phase information and is further configured to calculate the angular position of the rotor 14 at any specific instant of time based on a period of time between receipt of the rotor angular position pulse PP/phase information and the specific instant of time. Thereby, the tool controller 18 is able to operate the tool 12 to process specific portions or locations on the product P.

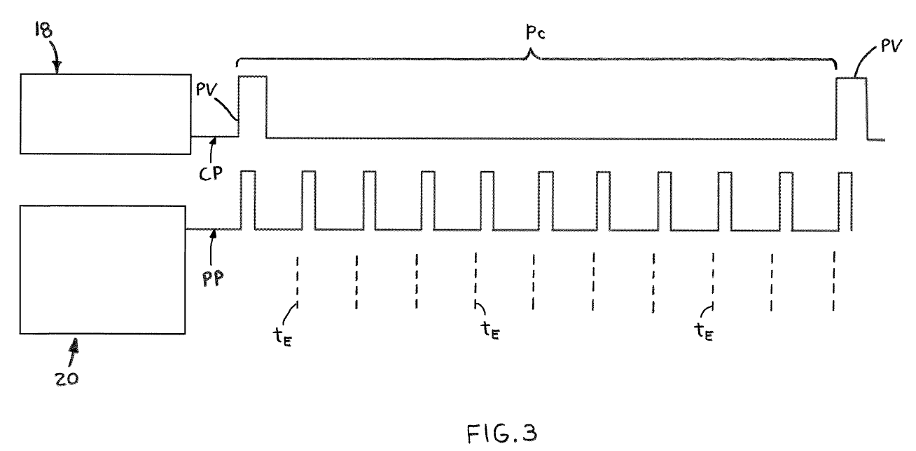

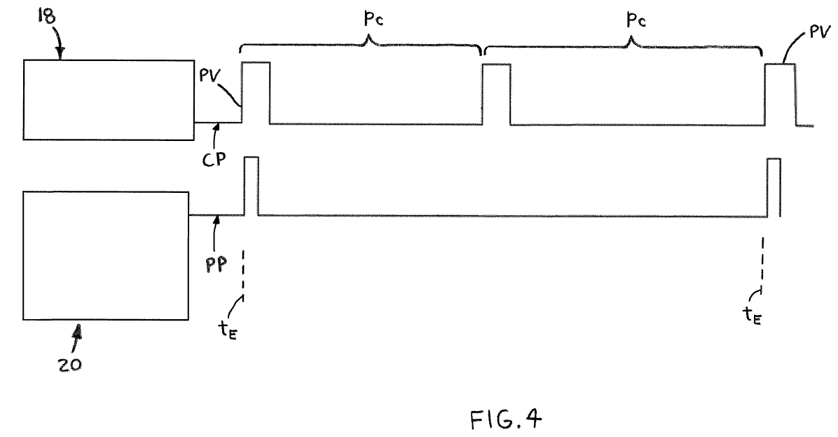

Referring to FIGS. 1, 3 and 4, the tool controller 18 is also configured to transmit a control pulse CP to the rotor controller 20 in order to command that the rotor 14 is angularly displacing at the desired speed as transmitted to the rotor controller 20 by the most recently received speed request signal SR. The control pulse CP is a pulse train with a constant period having a threshold value PV, which may be a rising edge, a maximum value/voltage or a falling edge, that repeats at the expiration of a control pulse period p_{C}. The control pulse period p_{C} is proportional to the period of rotation of the rotor 14 at the desired rotation speed of the most recently transmitted speed request signal SR. Specifically, the period p_{C} of the control pulse CP is a rational multiple or a whole fraction of the period of rotation of the rotor 14 at the desired speed or angular velocity. For example, the pulse period p_{C} may be ten times the desired rotation period, as shown in FIG. 3, or the pulse period p_{C} may be one-half the desired rotation period, as depicted in FIG. 4.

Referring now to FIGS. 3 and 4, the rotor controller 20 is further configured to calculate an expected time of position pulse transmission t_{E}, which is based on an anticipated period of the control pulse CP as determined by the rotation speed of the most recent speed request signal SR and prior history of control pulse periods p_{C}, and to compare the actual time of transmission of the rotor angular position pulse PP to the expected time of position pulse transmission t_{E} once every predetermined angular displacement of the rotor 14; preferably once every revolution of the rotor 14. The expected time of position pulse transmission t_{E} is stored within the memory of the rotor controller 20 and is used by the controller 20 to ensure that the rotor 14 is rotating at the desired speed of the most recent speed request signal SR. If the rotor 14 is rotating at the desired speed, a rotor angular position pulse PP should be sent to the tool controller 18 at each expected time of position pulse transmission t_{E}.

However, if there is a difference between the time that the angular position pulse PP is transmitted and the expected time of position pulse transmission t_{E}, the rotor controller 20 adjusts the rotation speed of the rotor 14, specifically by adjusting current through the rotor actuators 24 as discussed in further detail below. As used herein, each reference to an event occurring “at the same time” includes both events occurring substantially simultaneously and events occurring within a predetermined time interval or time offset and each reference to a “difference” between the timing of two events or events occurring at a “different time” means that the time between the two events is greater than a predetermined time interval/offset. Further, if the rotor controller 20 receives the control pulse threshold value PV at a time different than an expected time of position pulse transmission t_{E}, i.e., before or after the expected time of position pulse transmission t_{E} occurring at the frequency of the threshold value PV, the rotor controller 20 adjusts the rotation speed of the rotor 14 as necessary and recalculates the expected time of position pulse transmission t_{E}.

Further, the rotor controller 20 is also configured to compare a time when the threshold value PV of the control pulse CP is received with the most recent time that the angular position pulse PP is transmitted. If the threshold value PV is received at the same time that a position pulse PP is transmitted, the rotor 14 is angularly displacing at the desired speed of the most recent speed request signal SR and no action is taken by the rotor controller 20. However, if there is a difference between the time the control pulse peak PV is received and the time the most recent position pulse PP is transmitted, the rotor controller 20 adjusts the rotation speed of the rotor 14.

Thus, in the present processing system 10, the rotor controller 20 adjusts the rotation speed of the rotor 14 in each one of three circumstances: 1) the receipt of a different speed request signal SR from the tool controller 18; 2) when the position pulse PP is transmitted at a time different than the expected time of position pulse transmission t_{E}; and 3) when the threshold value PV of the control pulse CP is received at a time different than the time of transmission of the most recent position pulse PP. In each case, the rotor controller 20 adjusts electric current through the preferred actuators 24 as required to change the actual rotation speed of the rotor 14 to the desired rotation speed and/or at the desired angular phasing, as described in further detail below.

In view of the above, it is clear that the present control system 10 provides the benefits of simplified and accurate synchronization of the operation of a tool 12 with the rotation of a rotor 14. Such benefits are achieved due to the tool controller 18 sending out a continuous control pulse CP and separate speed request signals SR only when a change in rotor speed is necessary for tool operation, while the rotor controller 20 only transmits a position pulse PP at every completion of the predetermined angular displacement, typically once per revolution. Because of the minimization of data both transmitted by the rotor controller 20 and analyzed by the tool controller 18, the tool controller 18 is able to more precisely match tool processing operations with the angular position of the product P, while the rotor controller 20 is capable of relatively rapidly adjusting rotor rotation speed to the requirements of the tool controller 18. Also, any latency associated with digital communication of angular phase request and measured phase is eliminated. As a further result and benefit, the processing system 10 is able to operate at substantially higher rotor rotation speeds and tool processing speeds, thereby decreasing product processing times, increasing product quality, and increasing product production volume. Having described the basic components and operation above, these and other details of the processing system 10 of the present invention are described in further detail below.

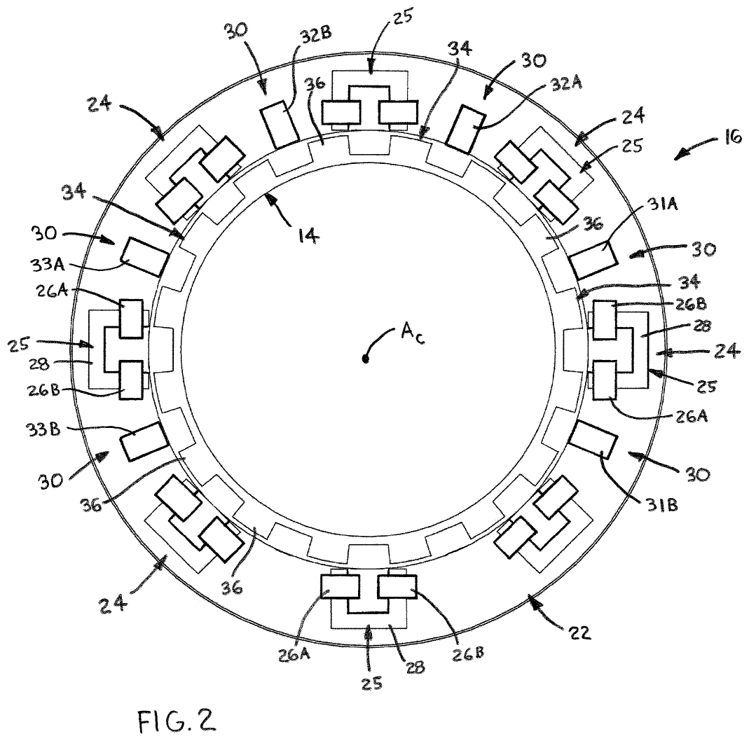

Referring particularly to FIG. 2, in order to determine the angular position of the rotor 14 so as to generate the once per revolution rotor position pulse PP, the rotor assembly 16 further includes at least one and preferably a plurality of rotation sensors 30, most preferably three pairs 31A/31B, 32A/32B and 33A/33B of the rotation sensors 30. Each rotation sensor 30 is configured to sense at least one feature 34 on the rotor 14 and to transmit a signal to the rotor controller 20 when the at least one feature 34 is detected. Then, the rotor controller 20 is configured to determine the angular position of the rotor 14 based on all of the signals from the one or more sensors 30.

Preferably, the rotor 14 includes a plurality of radially-outwardly extending teeth 36 spaced circumferentially about the central axis A_{C}. The preferred three pairs 31A/31B1, 32A/32B, 33A/33B of the sensors 30 are also spaced circumferentially apart about the central axis A_{C} and are mounted on the stator 22 so as to be positioned radially outwardly from the plurality of teeth 36. Each rotation sensor 30 is configured to detect each one of the teeth 32 and to transmit a signal indicating the detection of the one tooth 36 to the rotor controller 20. Based on these sensor signals, the rotor controller 20 is both able to determine when the rotor 14 has completed a predetermined angular displacement (e.g., each revolution of the rotor 14), and then generate the rotor position pulse PP, but is also able to determine the angular position of the rotor 14 at any instant in time and whether the rotor 14 is located at a desired angular position or phase. Further, each rotation sensor 30 is preferably an inductance proximity sensor.

Although the rotor assembly 16 preferably has three pairs of sensors 30, each formed as an inductance proximity sensor, and the rotor 14 preferably has a plurality of teeth 36 detected by the sensors 30, the rotor assembly 16 may have any appropriate arrangement and/or components capable of at least determining when the rotor 14 has completed each revolution during operation of the system 10. For example, the rotor 14 may include only a single feature 34, formed in any appropriate manner, and the rotor assembly 16 may include only a single sensor 30 that detects the one feature 34 once during every revolution of the rotor 14. Further for example, the sensor(s) 30 may be any other appropriate type of sensor, for example hall effect sensors, optical encoders, magnetic encoders, etc. and the rotor 14 may be provided within any type of feature(s) 32 that are detectable by the particular type of sensor utilized. The scope of the present invention includes all appropriate arrangements for at least detecting or determining each time that the rotor 14 completes a predetermined angular displacement about the central axis A_{C}, such as for example, one revolution, one hundred eighty degrees, etc.

Referring now to FIGS. 1 and 2, the stator 20 preferably includes a plurality of the actuators 24 spaced circumferentially about the perimeter of the rotor 14. Preferably, each actuator 24 is a reluctance motor actuator 25 which includes a pair of windings or coil assemblies 26A, 26B disposed about a ferromagnetic core 28, as depicted in FIG. 2. The coil assemblies 26A, 26B are connected with a current source (not depicted) such that current flowing through the coil assemblies 26A, 26B generates magnetic flux that passes through the core 28 and both into and out of the rotor 14, specifically the teeth 36, to thereby exert torque on the rotor 14. However, the actuator 24 may include only a single coil assembly or three or more coil assemblies (neither shown).

With such motor actuators 24 acting in coordination with levitation actuators and radial position actuators (neither shown), the rotor 14 is angularly displaced in a contactless manner that eliminates the need for mechanical roller bearings, bushings, seals or other components which may produce contaminants. However, the at least one actuator 24 may be any other appropriate device capable of angularly displacing the rotor 14 about the central axis A_{C}. For example, the actuator 24 may be provided by a single DC motor, an AC motor, etc. having an output shaft that mechanically drives rotation of the rotor 14, either directly or through an appropriate transmission device (no alternative structures shown).

In any case, the rotor controller 20 is configured to adjust the operation of the one or more actuators 24 whenever the controller 20 determines the need to adjust rotor speed. With the preferred motor actuators 25, the rotor controller 20 adjusts electric current through the pair of coil assemblies 26A, 26B, i.e., by adjusting the output of the current source, in order to adjust the rotor speed. More specifically, the rotor controller 20 increases current flow through the coil assemblies 26A, 26B to increase rotor speed and conversely decreases current flow, or inverts the phase of current flow, to decrease rotor speed. With other types of actuators 24, the rotor controller 20 adjusts the operation of the actuators 24 in an appropriate manner to accordingly vary the rotor speed as required.

Referring particularly to FIG. 1, the processing system 10 may further comprise one or more secondary tools 50 each configured to perform a process on the product 50 different than the processing conducted by the primary tool 12 and at least one secondary controller 52 configured to operate the secondary tool 50. For example, the “primary” tool 12 may include one or more heat lamps which perform an annealing operation on the product P and the one or more secondary tools 50 may be a gas injector, a laser, or any other tool for processing a rotating product P. When the processing system 10 includes a secondary tool 50 and a secondary tool controller 52, the “primary” tool controller 18 is further configured to transmit the control pulse CP to each secondary controller 52 to ensure that all processing being conducted on the product P is properly coordinated.

Representative, non-limiting examples of the present invention were described above in detail with reference to the attached drawings. This detailed description is merely intended to teach a person of skill in the art further details for practicing preferred aspects of the present teachings and is not intended to limit the scope of the invention.

Moreover, combinations of features and steps disclosed in the above detailed description may not be necessary to practice the invention in the broadest sense, and are instead taught merely to particularly describe representative examples of the invention. Furthermore, various features of the above-described representative examples, as well as the various independent and dependent claims below, may be combined in ways that are not specifically and explicitly enumerated in order to provide additional useful embodiments of the present teachings.

All features disclosed in the description and/or the claims are intended to be disclosed separately and independently from each other for the purpose of original written disclosure, as well as for the purpose of restricting the claimed subject matter, independent of the compositions of the features in the embodiments and/or the claims. In addition, all value ranges or indications of groups of entities are intended to disclose every possible intermediate value or intermediate entity for the purpose of original written disclosure, as well as for the purpose of restricting the claimed subject matter. The invention is not restricted to the above-described embodiments, and may be varied within the scope of the following claims.

We claim:

1. A system for processing a product during rotation, the system comprising:
a tool configured to perform a process on a product;
a rotor assembly including a rotor, the rotor being configured to support the product, and a stator including at least one actuator configured to exert magnetic torque on the rotor so as to angularly displace the rotor about a central axis;
a tool controller configured to operate the tool, to transmit a speed request signal including a desired rotation speed of the rotor and to transmit a control pulse having a threshold value repeating at the expiration of a pulse period, the pulse period being proportional to a desired period of rotation of the rotor at the desired rotation speed of the speed request signal; and
a rotor controller configured to receive the speed request signal and the control pulse, to control the at least one actuator of the stator such that the rotor angularly displaces at the desired rotation speed, to transmit a rotor angular position pulse to the tool controller once every predetermined angular displacement of the rotor, to compare a time when the threshold value of the control pulse is received with a time that the rotor angular position pulse is transmitted and to adjust rotation speed of the rotor when there is a difference between the time the control pulse threshold value is received and the time the rotor angular position pulse is transmitted.

2. The system as recited in claim 1, wherein the predetermined angular displacement is one revolution of the rotor.

3. The system as recited in claim 1, wherein the rotor controller is configured to calculate an expected time of position pulse transmission based on the desired speed of the speed request signal, to compare the time the rotor angular position pulse is transmitted to the expected time of position pulse transmission once every predetermined angular displacement of the rotor and to adjust the rotation speed of the rotor when there is a difference between the time the rotor angular position pulse is transmitted and the expected time of position pulse transmission.

4. The system as recited in claim 1, wherein the tool controller operates the tool based on the angular position of the rotor as determined by the tool controller using the rotor angular position pulse.

5. The system as recited in claim 4, wherein the tool controller includes a clock and is configured to calculate the angular position of the rotor at a specific instant of time based on a period of time between receipt of the rotor angular position pulse and the specific instant of time.

6. The system as recited in claim 1, wherein:
the rotor assembly further includes at least one rotation sensor configured to sense at least one feature on the rotor and to transmit a signal to the rotor controller when the at least one feature is detected; and
the rotor controller is configured to determine the angular position of the rotor based on signals from the at least one sensor.

7. The system as recited in claim 6, wherein:
the rotor has a plurality of teeth spaced circumferentially about the central axis;
the at least one rotation sensor is configured to detect each one of the teeth and to transmit a signal indicating the detection of one tooth to the rotor controller; and
the rotor controller is configured to determine the angular position of the rotor from the sensor signals.

8. The system as recited in claim 7, wherein the at least one rotation sensor includes a plurality of pairs of rotation sensors spaced circumferentially apart about the central axis.

9. The system as recited in claim 1, wherein the at least one actuator of the stator includes at least one coil assembly and the rotor controller is configured to adjust current through the at least one coil assembly to adjust the rotor speed.

10. The system as recited in claim 1, wherein:
the system further comprises a secondary tool configured to perform another process on the product and a secondary tool controller configured to operate the secondary tool; and
the tool controller is configured to send the control pulse to the secondary tool controller and the secondary tool controller operates the secondary tool based on the control pulse.

11. The system as recited in claim 1, wherein the tool includes at least one lamp configured to anneal one or more sections of the product.

12. A system for processing a product during rotation, the system comprising:
a tool configured to perform a process on the product;
a rotor assembly including a rotor, the rotor being configured to support the product, and a stator including at least one actuator configured to exert magnetic torque on the rotor so as to angularly displace the rotor about a central axis;
a tool controller configured to operate the tool, to transmit a speed request signal including a desired rotation speed of the rotor, and to transmit a control pulse having a threshold value repeating at the expiration of a pulse period, the pulse period being proportional to a desired period of rotation of the rotor at the desired rotation speed of the speed request signal; and
a rotor controller configured to receive the speed request signal, to control the at least one actuator of the stator such that the rotor angularly displaces at the desired rotation speed, to transmit a rotor position pulse and/or rotor phase information to the tool controller once every predetermined angular displacement of the rotor, to calculate an expected time of position pulse transmission based on the desired speed from the speed request signal, to compare the time the rotor angular position pulse is transmitted to the expected time of position pulse transmission once every predetermined angular displacement of the rotor and to adjust the rotation speed of the rotor when there is a difference between the time the rotor angular position pulse is transmitted and the expected time of position pulse transmission.

13. The system as recited in claim 12, wherein:
the tool controller is further configured to transmit a control pulse having a threshold value repeating at the expiration of a pulse period, the pulse period being proportional to a desired period of rotation of the rotor at the desired rotation speed of the speed request signal; and
a rotor controller further configured to receive the control pulse, to compare a time when the threshold value of the control pulse is received with a time that the rotor angular position pulse and/or rotor phase information is transmitted to the tool controller, and to adjust rotation speed of the rotor when there is a difference between the time the control pulse threshold value is received and the time the rotor angular position pulse and/or rotor phase information is transmitted.

14. The system as recited in claim 12, wherein the predetermined angular displacement is one revolution of the rotor.

15. The system as recited in claim 12, wherein the tool controller operates the tool based on the angular position of the rotor as determined by the tool controller using the rotor angular position pulse and/or the rotor phase information.

16. The system as recited in claim 15, wherein the tool controller includes a clock and is configured to calculate the angular position of the rotor at a specific instant of time based on a period of time between receipt of the rotor angular position pulse and/or rotor phase information and the specific instant of time.

17. The system as recited in claim 12, wherein:
the rotor assembly further includes at least one rotation sensor configured to sense at least one feature on the rotor and to transmit a signal to the rotor controller when the at least one feature is detected; and
the rotor controller is configured to determine the angular position of the rotor based on signals from the at least one sensor.

18. The system as recited in claim 17, wherein:
the rotor has a plurality of teeth spaced circumferentially about the central axis;
the at least one rotation sensor is configured to detect each one of the teeth and to transmit a signal indicating the detection of one tooth to the rotor controller; and
the rotor controller is configured to determine the angular position of the rotor from the sensor signals.

19. The system as recited in claim 18, wherein the at least one rotation sensor includes a plurality of pairs of rotation sensors spaced circumferentially apart about the central axis.

20. The system as recited in claim 12, wherein the at least one actuator of the stator includes at least one coil assembly and the rotor controller is configured to adjust current through the at least one coil assembly to adjust the rotor speed.
